(19) United States
(12) Patent Application Publication
(10) Pub. No.: US 2022/0140206 A1
(43) Pub. Date: May 5, 2022

(54) PHOSPHOR AND LIGHT IRRADIATION DEVICE

(71) Applicant: TDK CORPORATION, Tokyo (JP)

(72) Inventors: Mitsuru TAKAI, Tokyo (JP); Tatsuya TERUI, Tokyo (JP)

(73) Assignee: TDK CORPORATION, Tokyo (JP)

(21) Appl. No.: 17/427,808

(22) PCT Filed: Feb. 10, 2020
(86) PCT No.: PCT/JP2020/005135

§ 371 Date: Aug. 2, 2021

(30) Foreign Application Priority Data
Mar. 27, 2019 (JP) 2019-060935

(51) Int. Cl. H01L 33/50; H01S 5/02326; C09K 11/77; C01F 17/34

(52) U.S. Cl. CPC H01L 33/508; H01S 5/02326; C09K 11/7774; H01L 33/58; H01L 33/502; H01L 2933/0041; C01F 17/34

(57) ABSTRACT

A phosphor having a variable wavelength and a light irradiation device having said phosphor. This phosphor contains an activating agent, and has a concentration gradient of the activating agent along at least one direction.

### TECHNICAL FIELD

The present invention relates to a phosphor and a light emitting device using the phosphor.

### BACKGROUND

Patent Document 1 discloses a light emitting device that includes a blue light emitting diode which emits blue light, and a phosphor emitting yellow fluorescence when excited by receiving the blue light of the blue light emitting diode. The light emitting device of Patent Document 1 emits white light by mixing the yellow fluorescence with the blue light (blue transmitting light) transmitting through the phosphor. However, no study has been carried out regarding a phosphor having a fluorescence which can change a wavelength within one phosphor.
[Patent Document 1] Japanese Patent Application Laid Open No. 2015-81314

### SUMMARY

The present invention has been attained in view of such circumstances and the object is to provide a wavelength tunable phosphor, and a light emitting device using the phosphor.

The embodiments of the present invention for attaining the above-mentioned object are as follows.

[1] A phosphor including an activator, wherein the phosphor has a concentration gradient of the activator formed at least along one direction.

[2] The phosphor according to [1], wherein the phosphor is a columnar shape, and the phosphor has the concentration gradient of the activator along a longitudinal direction of the phosphor.

[3] The phosphor according to [1] or [2], wherein the concentration gradient of the activator is formed along a direction perpendicular to a direction of an optical path of a light transmitting through the phosphor.

[4] The phosphor according to any one of [1] to [3], wherein the phosphor is a single crystal.

[5] The phosphor according to any one of [1] to [4], wherein the activator is a heavy metal element or a rare earth element.

[6] The phosphor according to any one of [1] to [5], wherein an activator concentration represents a ratio of an amount of the activator with respect to an amount of elements other than oxygen included in the phosphor, and the activator concentration in the phosphor is 0.05 mol % or more and 20 mol % or less.

[7] The phosphor according to any one of [1] to [6], wherein a wavelength of a fluorescence of the phosphor is 530 nm to 645 nm.

[8] The phosphor according to any one of [1] to [7], wherein the activator is at least one selected from the group consisting of Ce, Pr, Sm, Eu, Tb, Dy, Tm, and Yb.

[9] The phosphor according to any one of [1] to [8], wherein the phosphor is generated by a micro pull-down method.

[10] A light emitting device including the phosphor according to any one of [1] to [9], and a means for changing an incident position of a light for exciting the phosphor emitted from a light source.

[11] The light emitting device according to [10] comprising the light source, and the light source is at least one of a blue light emitting diode and a blue semiconductor laser.

### BRIEF DESCRIPTION OF THE DRAWINGS

FIG. 1 is a front view of a light emitting device according to an embodiment of the present invention.

FIG. 2 is a schematic cross section of a single crystal manufacturing apparatus for manufacturing a phosphor according to an embodiment of the present invention.

FIG. 3 is a schematic diagram showing a method for producing the phosphor according to an embodiment of the present invention.

FIG. 4 is a front view of a light emitting device according other embodiment of the present invention.

FIG. 5 is a front view of a light emitting device according to other embodiment of the present invention.

FIG. 6 is a front view of a light emitting device according to other embodiment of the present invention.

FIG. 7 is a front view of a light emitting device according to other embodiment of the present invention.

FIG. 8 is a graph showing examples of the present invention.

FIG. 9 is a graph showing examples of the present invention.

FIG. 10 is a graph showing examples of the present invention.

### DETAILED DESCRIPTION

### First Embodiment

### 1. Light Emitting Device

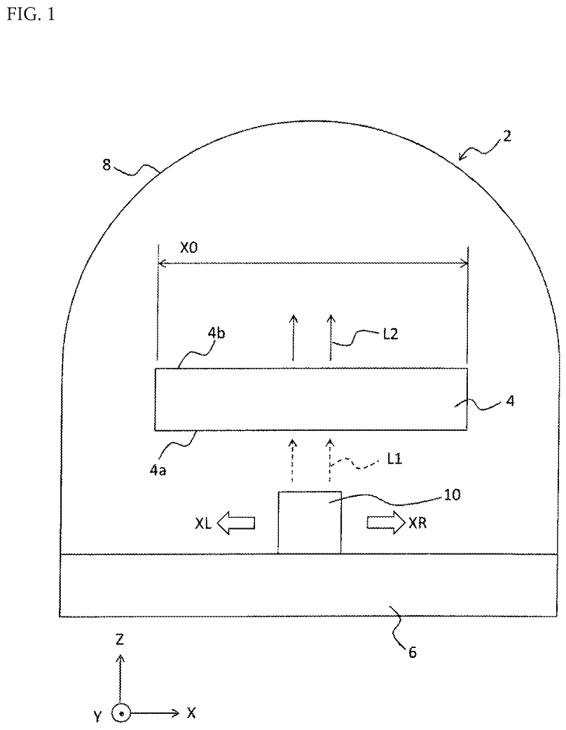

FIG. 1 shows a light emitting device 2 according to the present embodiment. The light emitting device 2 according to the present embodiment includes a phosphor 4 in a reflection board 6 and a cover 8, and a blue light emitting element 10. The blue light emitting element 10 is provided on the reflection board 6.

A material of the cover 8 is not particularly limited. As the material of the cover 8, for example a transparent glass or a resin may be mentioned.

As shown in FIG. 1, the blue light emitting element 10 emits blue light L1, which is excitation light for exciting the phosphor 4. Part of the blue light L1 incident on a first surface 4a of the phosphor 4 is absorbed by the phosphor 4, the part of the blue light L1 is wavelength-converted and emits fluorescence. The fluorescence emitted in this manner and the blue light L1 are mixed and emit white light L2 from a second surface 4b of the phosphor 4.

The phosphor 4 according to the present embodiment includes an activator, and as shown in FIG. 1, the phosphor 4 is a columnar shape of which a direction perpendicular to a light path of the blue light L1 is a longitudinal direction (X axis direction). In the phosphor 4 of the present embodiment, the activator gradually decreases along a direction of the arrow of X axis shown in FIG. 1, hence the phosphor 4 has a concentration gradient of the activator. When the same excitation light is irradiated to a part having a high activator concentration (high concentration part) and to a part having a low activator concentration (low concentration part), the fluorescence emitted from the high concentration part tends to have longer wavelength than the fluorescence emitted from the low concentration part.

In general, as the wavelength of the phosphor 4 becomes longer, color changes in the order of purple, indigo, blue, green, yellow, orange, and red. Purple is approximately within a range of 380 nm to 430 nm, indigo is approximately within a range of 430 nm to 460 nm, blue is approximately within a range of 460 nm to 500 nm, green is approximately within a range of 500 nm to 530 nm, yellow is approximately within a range of 530 to 590 nm, orange is approximately within a range of 590 nm to 650 nm, and red is approximately within a range of 650 nm to 780 nm. That is, according to the phosphor 4 of the present embodiment, in one phosphor 4, a fluorescence of purple, indigo, blue, green, yellow, orange, or red can be emitted by changing the part where the excitation light is irradiated to. Note that, within the wavelength ranges mentioned in above, the wavelengths partially overlap in each color. This is because color change is continuous change, therefore color and wavelength cannot be matched completely.

As shown in FIG. 1, the blue light emitting element 10 can move along the X axis direction in a direction of XL or XR. Therefore, by moving the blue light emitting element 10, the part irradiated by the blue light L1 in the phosphor 4 can be changed.

As mentioned in above, according to the phosphor 4 of the present embodiment, by changing the part of the phosphor 4 irradiated by the blue light L1, the wavelength of the emitted fluorescence can be changed. In other words, the color of the fluorescence can be changed. Therefore, by moving the blue light emitting element 10 along X axis direction in XL or XR direction on the reflection board 6 to change the part of the phosphor 4 irradiated by the blue light L1, the wavelength of the fluorescence emitted from the fluorescence 4 can be changed. In other words, the color of the fluorescence can be changed.

In general, the wavelength of the fluorescence used for a white light source is 530 nm to 540 nm, and the wavelength of the blue light L1 may be selected from 405 nm to 460 nm. Particularly, in general, the blue light L1 used for the white light source has the wavelength within a range of 425 nm to 460 nm. There is a deviation on a chromaticity table between these mixed lights and a JIS standard white color.

Also, in a conventional phosphor, a wavelength of a fluorescence generated by receiving an excitation light was fixed in one phosphor. Therefore, the wavelength of the fluorescence in one phosphor could not be changed.

According to the present embodiment, as mentioned in above, the color of the fluorescence emitted from the phosphor 4 can be changed. As a result, the color of the fluorescence can be finely adjusted in order to make the white light L2 obtained by mixing the blue light L1 and the fluorescence closer to a desired white color L2. Specifically, according to the present embodiment, the wavelength of the fluorescence can be finely adjusted to obtain the white light L2 of JIS standard white color.

The wavelength of the fluorescence of the phosphor 4 according to the present embodiment is not particularly limited. In the phosphor 4 according to the present embodiment, in one phosphor, the wavelength of the fluorescence may be preferably changed within a range of 380 nm to 780 nm, more preferably within a range of 530 nm to 645 nm, and further preferably 534 nm to 630 nm.

### 1-2. Blue Light Emitting Element

The blue light emitting element 10 of the present embodiment is a light source for exciting the phosphor 4. Also, the blue light emitting element 10 of the present embodiment emits the white light L2 by mixing with the fluorescence, and also the blue light emitting element 10 can emit the blue light L1 which can be wavelength-converted to a fluorescence by the phosphor 4. As such blue light emitting element 10, for example a blue light emitting diode (blue LED) or a blue semiconductor laser (blue light LD) may be mentioned.

### 1-3. Phosphor

The phosphor 4 shown in FIG. 1 is a columnar shape, and is a single crystal. For example, a crystal peak of αAG single crystal (a represents an element α shown in below) can be verified by XRD to confirm that phosphor 4 is a single crystal.

Since the phosphor 4 is a single crystal, a transmittance of the blue light L1 can be improved compared to transparent ceramics or eutectics. This is because the transmittance of transparent ceramics tends to decrease due to light scattering at grain boundaries and the transmittance of eutectics tends to decrease due to light scattering at phase boundaries. Therefore, the single crystal phosphor 4 has a higher luminance than transparent ceramics or eutectics.

A composition of the phosphor 4 of the present embodiment is not particularly limited. As the composition of the phosphor 4 of the present embodiment, for example, a composition adding a small amount of the activator such as a heavy metal element or a rare earth element to sulfides such as zinc sulfide and the like, or inorganic substances such as silicate, borate, rare earth element salt, uranyl salt, platinum cyan complex salt, tungstate, and the like may be mentioned.

The heavy metal element used as the activator of the phosphor 4 according to the present embodiment is not particularly limited. The heavy metal element used as the activator of the phosphor 4 according to the present embodiment may for example be Mn, Cr, and the like.

The rare earth element used as the activator of the phosphor 4 according to the present embodiment is not particularly limited. The rare earth element used as the activator of the phosphor 4 according to the present embodiment may for example be at least one selected from the group consisting of Ce, Pr, Sm, Eu, Tb, Dy, Tm, and Yb.

Specifically, the composition of the phosphor 4 according to the present embodiment may for example be α₃Al₅O₁₂:β³⁺ (“α” is an element a described below, and “β” is an element β described below), CaGa₂S₄:Eu²⁺, (Sr,Ca,Ba)₂SiO₄:Eu²⁺, (Sr,Ca)S:Eu²⁺, (Ca,Sr)₂Si₅N₈:Eu²⁺, CaAlSiN₃:Eu²⁺, (Sr,Ba)₃SiO₅:Eu²⁺, K₂SiF₆:Mn, Y₃(Al,Ga)₅O₁₂:Ce³⁺, SrGa₂S₄:Eu²⁺, (Ba,Sr)₂SiO₄:Eu²⁺, Ca₃Sc₂Si₃O₁₂:Ce³⁺, CaSc₂O₄:Ce³⁺, (Sr,Ba)Si₂O₂N₂:Eu²⁺. Ba₃Si₆O₁₂N₂:Eu²⁺, and the like.

The composition of the phosphor 4 according to the present embodiment may preferably be α₃Al₅O₁₂:β³⁺. α₃Al₅O₁₂:β³⁺ is represented by (α₁₋ₓβₓ)₃₊ₐAl₅₋ₐO₁₂ (0.0001≤x≤0.007, −0.016≤a≤0.315).

The element α is at least one selected from the group consisting of Y, Lu, Gd, Tb, and La. Note that, the element a may preferably at least include Y. As the element α includes Y, a luminance can be improved.

The element β is an activator. The element β may preferably be at least one selected from the group consisting of Ce, Pr, Sm, Eu, Tb, Dy, Tm, and Yb. Thereby, the phosphor 4 can attain a high luminance, and also the wavelength of the fluorescence can be 530 nm to 645 nm. The element β may preferably be Ce or Eu, and more preferably Ce.

In the present embodiment, “an activator concentration” represents a ratio of the amount of the activator with respect to the amount of the elements other than oxygen included in the phosphor 4.

The activator concentration of the phosphor 4 in the present embodiment is not particularly limited. The minimum value of the activator concentration of the phosphor 4 according to the present embodiment may preferably be 0.05 mol % or more. Thereby, the luminance of the fluorescence can be increased. The minimum value of the activator concentration of the phosphor 4 according to the present embodiment may more preferably be 0.1 mol % or more.

The maximum value of the activator concentration of the phosphor 4 in the present embodiment may preferably be 20 mol % or less. Thereby, a decrease in the transmittance due to the formation of the different phases can be prevented. The maximum value of the activator concentration of the phosphor 4 according to the present embodiment may further preferably be 15 mol % or less.

The phosphor 4 according to the present embodiment has a concentration gradient of which the activator concentration gradually decreases along the direction of the arrow of X axis shown in FIG. 1. A degree of the concentration gradient of the activator concentration of the phosphor 4 according to the present embodiment is not particularly limited. When R mol %/mm represents a difference of the activator concentration per 1 mm, R (mol %/mm) may preferably be 0.05 mol %/mm to 5 mol %/mm, and more preferably it may be 0.1 mol %/mm to 2 mol %/mm.

The activator concentration of the phosphor 4 can be measured by LA-ICP-MS, EPMA, EDX, and the like.

### 2. Method of Manufacturing Phosphor

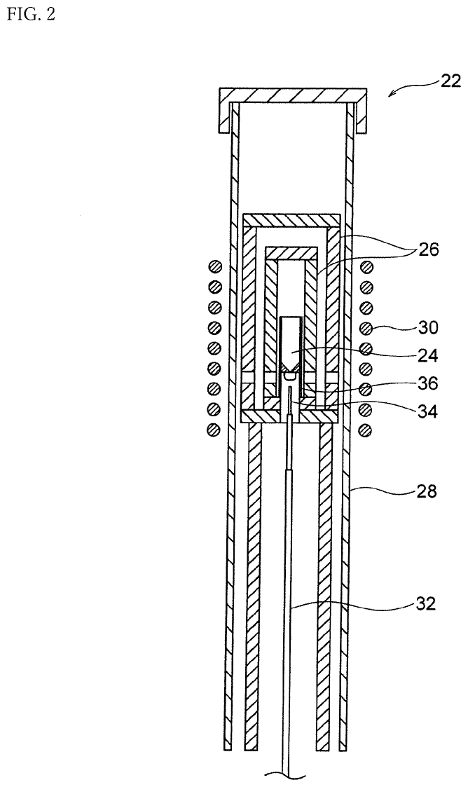

FIG. 2 is a schematic cross section of a single crystal manufacturing apparatus 22 based on a micro-pull-down method (μ-PD method), which is an apparatus for manufacturing the phosphor 4 of the present embodiment. The μ-PD method is a melt solidification method in which a crucible 24 containing a sample is directly or indirectly heated to obtain a melt of a target substance in the crucible 24, then a seed crystal 34 installed below the crucible 24 is brought into contact with an opening portion at the lower end of the crucible 24. The seed crystal 34 is pulled down while a solid-liquid interface is formed there, and a single crystal is grown as a result.

In the melt solidification method, the single crystal grows while the activator moves to a lower temperature area. When individual parts are cut out from the single crystal being generated, the phosphor 4 having a predetermined concentration gradient of the activator is obtained from each position being cut out. Particularly, in the μ-PD method, the direction G, which is the direction that the seed crystal 34 is pulled down, coincides with the longitudinal direction of the phosphor 4 (X0 direction). In other words, the direction G, which is the direction that the seed crystal 34 is pulled down, coincides with the vertical direction of the optical path of the blue light L1 transmitted through the phosphor 4.

Since the phosphor 4 according to the present embodiment is generated by the μ-PD method, the phosphor 4 is more likely to have the concentration gradient of the activator than the phosphor generated by the conventional Czochralski method (CZ method). Hence, the phosphor 4 according to the present embodiment may preferably be generated by the μ-PD method.

As shown in FIG. 2, the single crystal manufacturing apparatus 22 for manufacturing the phosphor 4 according to the present embodiment includes the crucible 24 installed such that the opening portion is directed downward, and a refractory furnace 26 surrounding the crucible 24. Further, the refractory furnace 26 is covered with a quartz tube 28, and an induction heating coil 30 for heating the crucible 24 is installed near a lengthwise center of the quartz tube 28.

The seed crystal 34 held by a seed crystal holding jig 32 is installed in the opening portion of the crucible 24. In addition, an after heater 36 is installed near the opening portion of the crucible 24.

Although it is not shown in the figures, the single crystal manufacturing apparatus 22 is provided with a decompression means for decompressing the inner portion of the refractory furnace 26, a pressure measuring means for monitoring decompression, a temperature measuring means for measuring the temperature of the refractory furnace 26, and a gas supply means (not illustrated) for supplying an inert gas into the refractory furnace 26.

A single crystal cut into a rod shape is used as the seed crystal 34. The seed crystal 34 includes elements constituting the desired phosphor 4, and preferably the seed crystal 34 may be a single crystal which does not include the activator.

The material of the seed crystal holding jig 32 is not particularly limited. Preferably, for example, it may be dense alumina which is scarcely influenced at around 1900° C. as a use temperature. The shape and size of the seed crystal holding jig 32 are not particularly limited. Preferably, it may be a rod shape with a diameter which does not contact with the refractory furnace 26.

The single crystal has a high melting point, and thus the material of the crucible 24 and the after heater 36 may preferably be Ir, Mo, and the like. In addition, more preferably the material of the crucible may be Ir to prevent foreign matter from mixing into the single crystal as a result of oxidation of the material of the crucible 24. Note that, Pt can be used as the material of the crucible 24 in case a target is a substance having a melting point of 1500° C. or less. Also, crystal growth in the atmosphere is possible in case Pt is used as the material of the crucible 24. In case a target is a substance having a high melting point exceeding 1500° C., Ir and the like are used as the material of the crucible 24 and the after heater 36, and thus crystal growth is performed only under an inert gas atmosphere such as Ar.

The opening portion of the crucible 24 may have a diameter of approximately 200 μm to 400 μm and a flat shape, considering the low viscosity of the single crystal melt and the wettability against the crucible 24.

A material of the refractory furnace 26 is not particularly limited, and it may preferably be alumina considering a heat retention property, a use temperature, and also from the point of preventing contamination caused by impurities mixed into the crystal.

Next, a method for manufacturing the phosphor 4 (single crystal) according to the present embodiment will be described in detail. In below, a method for manufacturing an αAG:Ce based phosphor 4 is particularly described.

First, an αAG raw material and Ce as raw materials of a single crystal are placed into the crucible 24 inside the refractory furnace 26, and the inside of the furnace is substituted with an inert gas such as N₂ and Ar.

Next, the crucible 24 is heated by the induction heating coil (high frequency coil for heating) 30 while flowing the inert gas at 10 to 100 cm³/min, and the raw material is melted, thereby the melt is obtained.

When the raw material is thoroughly melted, the seed crystal 34 is gradually brought closer from the lower portion of the crucible, and the seed crystal 34 is brought into contact with the opening portion at the lower end of the crucible 24. When the melt comes out from the opening portion at the lower end of the crucible 24, the seed crystal 34 is lowered and crystal growth is initiated.

The speed of lowering the seed crystal 34 is referred as “a growth rate”. Note that, the concentration gradient of the activator in the crystal can be regulated by changing this growth rate. When the growth rate is low, the activator concentration tends to decreases; and when the growth rate is high, the activator concentration tends to increase.

In the present embodiment, the growth rate is low at first, and then the growth rate is gradually made higher, thereby the concentration gradient of the activator in the crystal can be formed. Alternatively, the growth rate can be high at first, and then the growth rate can be made gradually lower, thereby the concentration gradient of the activator in the crystal can be formed. However, a method of forming the concentration gradient of the activator is not particularly limited to these.

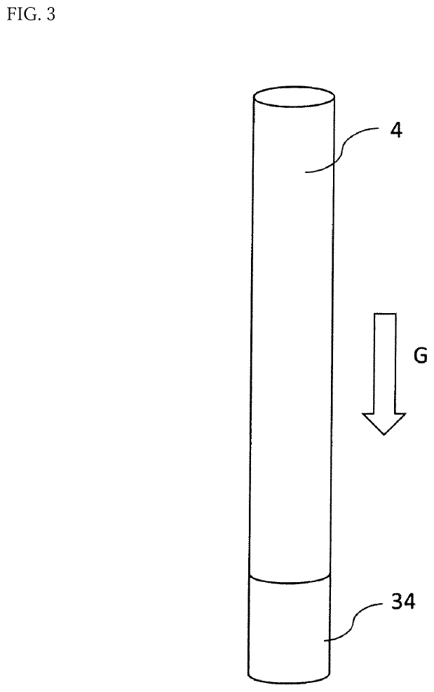

In the present embodiment, preferably, the growth rate is low at first and then the growth rate is made gradually higher because a stable crystal growth can be attained. In this case, the phosphor 4 shown in FIG. 3 has a low activator concentration at a lower part closer to the seed crystal 34, and has a high activator concentration at an upper part which is further away from the seed crystal 34.

The growth rate of the present embodiment is not particularly limited. For example, the growth rate of the present embodiment may be varied within a range of 0.01 mm/min to 30 mm/min, more preferably within a range of 0.01 mm/min to 0.20 mm/min.

The growth rate and temperature are controlled together manually while observing a solid-liquid interface by a CCD camera or a thermo camera.

Due to the movement of the induction heating coil 30, a temperature gradient can be selected from a range between 10° C./mm and 100° C./mm.

The seed crystal 34 is lowered until the melt in the crucible 24 does not flow out, and after the seed crystal 34 is separated from the crucible 24, cooling is performed in a manner which does not form a crack in the single crystal. It is possible to increase the rate of melt withdrawal by setting a steep temperature gradient between the crucible 24 and the after heater 36 and below as described above, the growth rate can be made faster.

During the above-mentioned crystal growth and cooling, the inert gas keeps flowing into the refractory furnace 26 under the same conditions as during the heating. Preferably, an inert gas such as N₂, Ar, and the like are used as the atmosphere in the furnace.

### 3. Summary of Present Embodiment

The phosphor according to the present embodiment includes the activator, and has the concentration gradient of the activator along at least one direction.

Thereby, the fluorescence having a desired wavelength from ultraviolet to infrared can be obtained, and the phosphor having a wavelength controllability can be obtained.

The phosphor 4 according to the present embodiment is a columnar shape, and has the concentration gradient of the activator along the longitudinal direction of the phosphor.

Thereby, the wavelength controllability of the phosphor 4 can be further enhanced.

The phosphor 4 according to the present embodiment has the concentration gradient of the activator along a direction perpendicular to a direction of the optical path transmitting through the phosphor 4.

Thereby, the effect of wavelength controllability of the phosphor 4 tends to be exhibited easily.

The phosphor 4 according to the present embodiment is a single crystal.

Thereby, the transmittance of the phosphor 4 is increased, and the luminance can be increased.

The activator of the phosphor 4 according to the present embodiment is a heavy metal element or a rare earth element.

Thereby, the luminance of the phosphor 4 can be increased.

In the phosphor 4 according to the present embodiment, the activator concentration represents a ratio of an amount of the activator with respect to an amount of elements other than oxygen included in the phosphor 4, and the minimum value of the activator concentration in the phosphor 4 is 0.05 mol % and the maximum value is 20 mol % or less.

Thereby, the transmittance of the phosphor 4 is increased, and the luminance can be increased.

The wavelength of the fluorescence of the phosphor 4 according to the present embodiment is 530 nm to 645 nm.

Thereby, the white light L2 obtained by mixing the blue light L1 and the fluorescence can be made closer to the desired white color.

The activator of the phosphor 4 according to the present embodiment is at least one selected from the group consisting of Ce, Pr, Sm, Eu, Tb, Dy, Tm, and Yb.

Thereby, the phosphor 4 can attain a high luminance, and the wavelength of the fluorescence can be 530 nm to 645 nm.

The phosphor 4 according to the present embodiment is produced by a micro pull-down method.

Thereby, a phosphor having a concentration gradient tends to be produced easily. Also, a micro pull-down method has a faster growth rate and has an excellent shape controllability.

The light emitting device 2 according to the present embodiment includes the phosphor 4, and the means for changing the incident position of the light for exciting the phosphor 4 emitted from a light source.

According to the phosphor 4 of the present embodiment, by changing the part where the excitation light is irradiated on the phosphor 4, the wavelength of the fluorescence emitted from the phosphor 4 can be changed. In other words, the color of the fluorescence can be changed. Therefore, by changing the incident position of the light from the light source onto the phosphor 4, the wavelength of the fluorescence emitted from the phosphor 4, that is the color of the fluorescence, can be changed.

The light emitting device 2 according to the present embodiment includes the light source, and the light source is at least one of a blue light emitting diode and a blue semiconductor laser.

When the light source is the blue light emitting element 10 which emits such blue light L1, by mixing the blue light L1 and a yellow fluorescence from the phosphor 4, the white light L2 can be obtained; and by mixing the blue light L1 with green and red of the phosphor 4, the white light L2 can be obtained.

### Second Embodiment

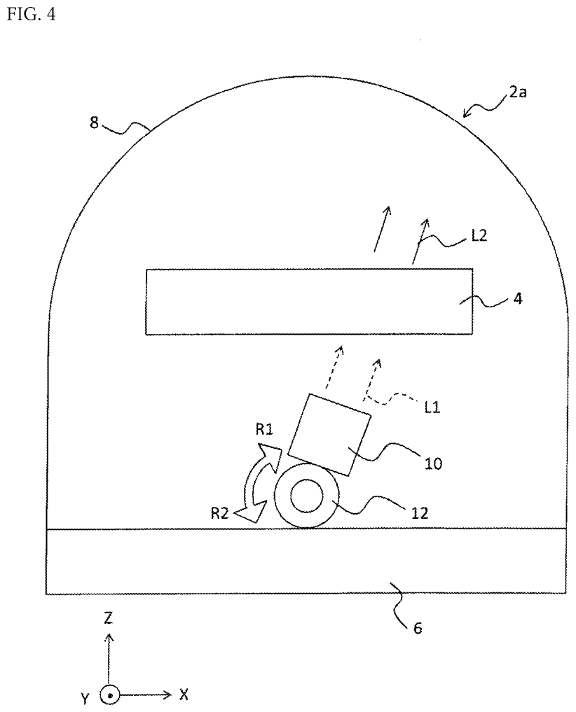

A light emitting device 2a according to the present embodiment is same as the light emitting device 2 of the first embodiment except for described in below. In the light emitting device 2a according to the present embodiment, as shown in FIG. 4, the blue light emitting element 10 is fixed to a rotating unit 12, and the rotating unit 12 is rotated to a direction of R1 or R2, thereby an incident position of the blue light L1 emitted from the blue light emitting element 10 onto the phosphor 4 can be changed.

Note that, the white light L2 of FIG. 4 is tilted from a direction perpendicular to a bottom of the light emitting device 2a. The light emitting direction of the white light L2 can be adjusted to a perpendicular direction against the bottom of the light emitting device 2a for example by a passing the white light L2 through a polarizing unit.

Also, although it is not shown in the figures, on the contrary to FIG. 4, the phosphor can be fixed to the rotating unit, and by rotating the rotating unit, the incident position of the blue light emitted from the blue light emitting element on the phosphor may be changed.

### Third Embodiment

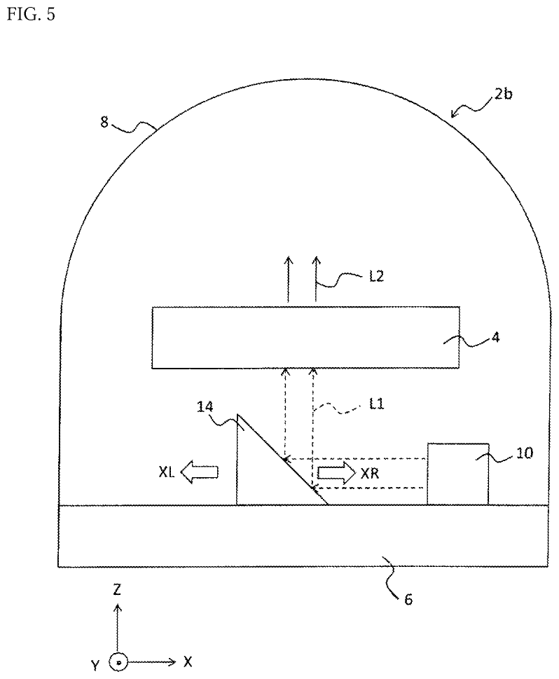

A light emitting device 2b according to the present embodiment is same as the light emitting device 2 of the first embodiment except for described in below. As shown in FIG. 5, the light emitting device 2b according to the present embodiment is provided with a reflection unit 14 capable of moving in a direction of XL or XR which is parallel to X axis direction. That is, the blue light L1 from the blue light emitting element 10 is reflected by the reflection unit 14 which is capable of moving; thereby the incident position of the blue light L1 emitted from the blue light emitting element 10 onto the phosphor 4 can be changed.

### Fourth Embodiment

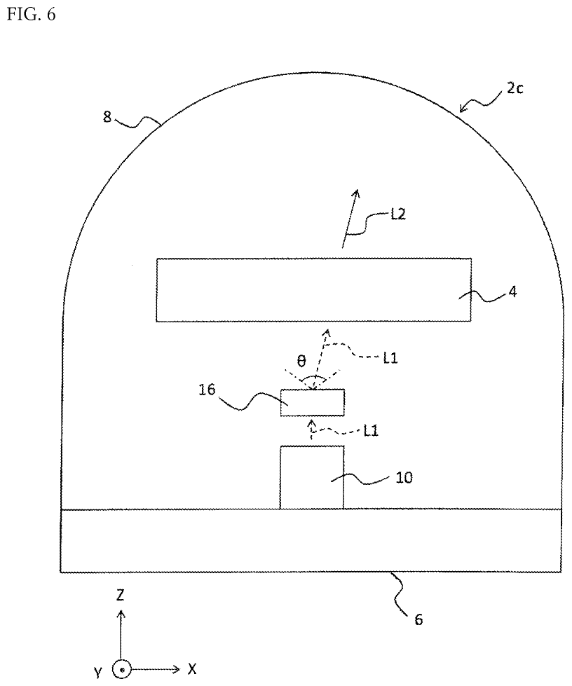

A light emitting device 2c according to the present embodiment is same as the light emitting device 2 of the first embodiment except for described in below. As shown in FIG. 6, the light emitting device 2c according to the present embodiment includes a polarizing unit 16 capable of polarizing the blue light L1 within a range of an angle θ which is an angle defined with reference to a direction parallel to an incident direction of the blue light L1. That is, the blue light L1 from the blue light emitting element 10 is polarized by the polarizing unit 16, thereby the incident position of the blue light L1 emitted from the blue light emitting element 10 onto the phosphor 4 can be changed.

Note that, the white light L2 of FIG. 6 is tilted from a direction perpendicular to a bottom of the light emitting device 2c. The light emitting direction of the white light L2 can be adjusted to a perpendicular direction against the bottom of the light emitting device 2c for example by a passing the white light L2 through other polarizing unit which is not shown in the figure.

### Fifth Embodiment

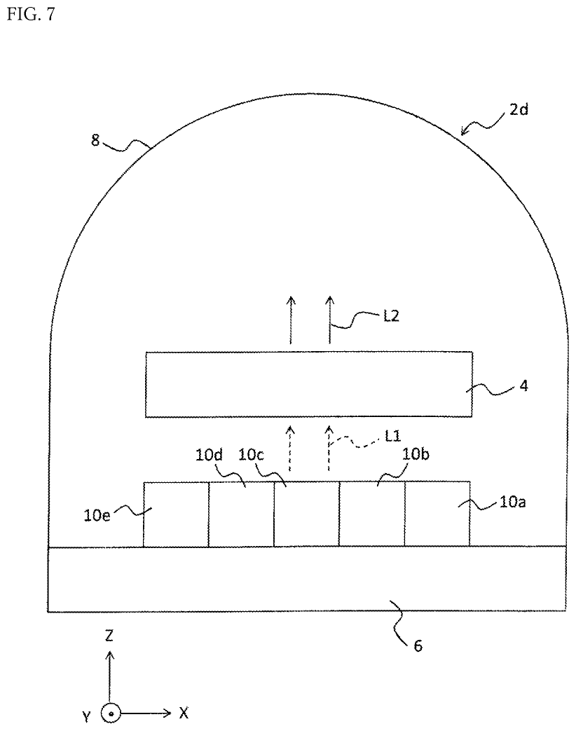

A light emitting device 2d according to the present embodiment is same as the light emitting device 2 of the first embodiment except for described in below. As shown in FIG. 7, the light emitting device 2d according to the present embodiment includes a plurality of blue light emitting elements 10a to 10e which are provided along a parallel direction to the X axis direction. That is, a blue light emitting element which emits the blue light L1 is selected from the plurality of blue light emitting elements 10a to 10e; thereby the incident position of the blue light L1 emitted from a blue light emitting element onto the phosphor 4 can be changed.

### Sixth Embodiment

A light emitting device according to the present embodiment is same as the light emitting device 2 of the first embodiment except for described in below. The light emitting device according to the present embodiment emits a blue light to a phosphor from a blue light emitting element through an optical fiber. According to this method, by moving a position of a tip of the optical fiber at the phosphor side, the incident position of the blue light emitted from a blue light emitting element onto the phosphor can be changed.

The present invention is not limited to the above-described embodiments, and various modifications may be performed within the scope of the present invention.

For example, a shape of the phosphor is not particularly limited, and it may be a columnar shape in which a cross section parallel to the optical path is polygonal, circle, or oval. Also, regarding the shape of the phosphor, a cross section perpendicular to the optical path may be a disk shape of a circular disk shape or an oval disk shape, or it may be a spheric shape or a rugby ball shape.

Also, in the above-mentioned embodiments, as the light source for exciting the phosphor 4, the blue light emitting element 10 is used, however instead of the blue light emitting element 10, a purple light emitting element may be used. When the purple light emitting element is used, the phosphor of blue, green, and red can be excited by the purple light emitting element, thereby a white light may be obtained.

A composition of the phosphor which can be excited by the light emitted from the purple light emitting element is not particularly limited. As the composition of the phosphor which can be excited by the light emitted from the purple light emitting element, for example, (Sr,Ca)S:Eu²⁺; (Ca,Sr)₂Si₅N₈:Eu²⁺; CaAlSi₅N₈:Eu²⁺; CaAlSiN₃:Eu²⁺; La₂O₂S:Eu³⁺; LiEuW₂O₈; 3.5MgO.0.5MgF₂.GeO₂:Mn⁴⁺; (Sr,Ca,Ba,Mg)₁₀(PO₄)₆Cl₂:Eu²⁺,Mn²⁺; Ba₃MgSi₂O₈:Eu²⁺,Mn²⁺; SrGa₂S₄:Eu²⁺; SrSi₂O₂N₂:Eu²⁺; Ba₃Si₆O₁₂N₂:Eu²⁺; BaMgAl₁₀O₁₇:Eu²⁺,Mn²⁺; SrAl₂O₄:Eu²⁺; (Sr,Ca,Ba,Mg)₁₀(PO₄)₆Cl₁₂:Eu²⁺; (Ba,Sr)MgAl₁₀O₁₇:Eu²⁺; SrSi₉Al₁₉ON₃₁:Eu²⁺; (Sr,Ba)₃MgSi₂O₈:Eu²⁺; and the like may be mentioned.

In the present invention, a method of changing the incident position of the blue light L1 emitted onto the phosphor 4 is not particularly limited.

For example, the position of the blue light emitting element 10 may be fixed, and the phosphor 4 may be moved to change the incident position of the blue light L1 emitted onto the phosphor 4.

For example, the blue light emitting element 10 and the phosphor 4 may be moved to change the incident position of the blue light L1 emitted onto the phosphor 4.

In the above-mentioned phosphor 4, the activator concentration gradually decreases along the direction of arrow of X axis shown in FIG. 1, however, a form of the concentration gradient of the activator is not particularly limited. For example, the activator concentration may gradually decrease in the opposite direction of the arrow of X axis. Also, the activator concentration may have a plurality of inflection points in which the activator gradually decreases along the direction of arrow of X axis, and then gradually increases.

For example, a surface part of the phosphor 4 may have the concentration gradient of the activator; and the activator concentration at the surface part of the phosphor 4 may be higher than the activator concentration at a center part of the phosphor 4.

When the activator concentration in the phosphor 4 is too high, the transmittance tends to decrease. The phosphor 4 can have an appropriate transmittance by having the concentration gradient of the activator at the surface part of the phosphor 4; and also, by having a higher concentration of the activator at the surface part of the phosphor 4 than at the center part of the phosphor 4.

An area which is considered as the surface part of the phosphor 4 is not particularly limited. When “m” represents a distance from the outer most surface to the center of the phosphor 4 in the cross section parallel to the optical path of the blue light L1 of the phosphor 4, for example, the surface part of the phosphor 4 may be an area included in 20% of the distance of “m” of which “m” is the distance from the outer most surface of the cross section to the center part, and more preferably 10% of the distance of “m” of which “m” is the distance from the outer most surface of the cross section to the center part.

An area which is considered as the center part of the phosphor 4 is not particularly limited. For example, area other than the surface part of the phosphor 4 may be considered as the center part of the phosphor 4.

The activator concentration in the center part of the phosphor 4 may be higher than the concentration of the activator at the surface part of the phosphor 4. Note that, preferably the activator concentration in the surface part of the phosphor 4 may be higher than the activator concentration in the center part of the phosphor 4, since an appropriate transmittance tends to be obtained easily.

Note that, a method of making a higher activator concentration at the surface part of the phosphor 4 than the center part of the phosphor 4 is not particularly limited, and also a method of providing the concentration gradient only to the surface part is not particularly limited. For example, by adjusting the growth rate of the single crystal, the activator concentration at the surface part of the phosphor 4 can be made higher than the activator concentration at the center part of the phosphor 4. Also, for example, by adjusting a temperature of growth atmosphere, the concentration gradient of the activator may only be formed at the surface part of the phosphor 4.

The concentration gradient of the activator in the phosphor 4 can be obtained not only by growing the single crystal which becomes the phosphor 4 by a μ-PD method, or by controlling the temperature to equal or lower than the temperature of the crucible 24 by the after heater 36; but also, the concentration gradient of the activator in the phosphor 4 can be obtained by growing the phosphor 4 by an EFG method. Note that, an EFG method is a method of growing the crystal by melting the raw material placed inside the crucible by heating, and guiding the raw material to an opening portion of a slit die placed vertically in the crucible, then pulling out the seed crystal while the raw material is in contact with the seed crystal at this opening portion.

The phosphor 4 according to the present invention can be used for example for automobile head lights, a fluorescent lamp, a fluorescent screen, a luminous paint, an electroluminescence, a scintillation counter, a cathode-ray tube, a decorative light, and the like.

When the phosphor 4 according to the present invention is used for the automobile head lights, a color temperature of the automobile head lights can be adjusted to a desired white light, and also a color temperature of the automobile head lights can be adjusted to yellow to be used as a fog lamp.

### Examples

Hereinafter, the present invention is described based on further detailed examples, however the present invention is not limited thereto.

A Ce:YAG (Yttrium Aluminum Garnet) single crystal was generated by a μ-PD method using a single crystal manufacturing apparatus 22 shown in FIG. 2.

As starting materials, 10 pats by mass of a YAG raw material was introduced into a crucible 24 made of Ir having an inner diameter of 20 mm and Ce as the activator were introduced into the crucible 24. The crucible 24 introduced with the raw materials was placed into a refractory furnace 26, and a pressure inside the refractory furnace 26 was set to a reduced-pressure atmosphere, and N₂ gas was flown at a flow rate of 50 cm³/min.

Then, heating of the crucible 24 was initiated, and the crucible 24 was heated for 1 hour until reaching to a melting point of the YAG single crystal. The YAG single crystal was used as a seed crystal 34, and a temperature of the seed crystal 34 was increased close to the melting point of YAG.

The tip of the seed crystal 34 was brought into contact with an opening at the lower end of the crucible 24, and the temperature was gradually increased until a melt flew out from the opening portion. When the melt flew out from the opening portion at the lower end of the crucible 24, the seed crystal 34 was gradually lowered down, initially at a rate of 0.01 mm/min and at the end in a rate of 0.2 mm/min to perform a crystal growth by gradually changing a growth rate.

As a result, the Ce:YAG single crystal having a diameter of 5 mm and a longitudinal length of 93 mm was obtained.

This Ce:YAG single crystal was cut out into a square columnar shape of 2 mm×2 mm and a longitudinal length (X0) of 55 mm.

The single crystal being cut out was evaluated by a method described in below. Note that, wavelength and transmittance of a fluorescence were measured for the single crystal being cut out from points on the center part of a short length direction and 5 mm spaced apart with each other along the line of longitudinal direction.

Single Crystal

Crystal peaks of the YAG single crystal were observed by XRD to verify that no different phase was included, thereby the single crystal was confirmed.

Wavelength of Fluorescence

The wavelength of the fluorescence was measured at 25° C., 200° C., and 300° C. using a F-7000 fluorescence spectrophotometer made by Hitachi High-Tech Corporation. Mode of measurement was fluorescent spectrum, and measuring conditions were an excitation wavelength of 450 nm and a photomultiplier voltage of 400V.

Transmittance

The transmittance was measured by a V660 spectrometer made by JASCO Corporation. The measuring wavelength was 390 nm.

TABLE 1

| Distance from end in | Activator | Wavelength of | | |
|---|---|---|---|---|
| longitudinal direction | concentration | fluorescence | Color of | Transmittance |
| [mm] | [%] | [nm] | fluorescence | [%] |
| 5 | 0.03 | 520 | Green | 77.0% |
| 10 | 0.05 | 530 | Yellow-green | 76.9% |
| 15 | 0.1 | 534 | Yellow | 76.9% |
| 20 | 0.7 | 540 | Yellow | 76.0% |
| 25 | 1 | 542 | Yellow | 75.6% |
| 30 | 5 | 565 | Yellow | 69.9% |
| 35 | 10 | 600 | Orange | 62.8% |
| 40 | 15 | 630 | Orange | 55.7% |
| 45 | 20 | 645 | Orange | 50.0% |
| 50 | 25 | 655 | Red | 41.4% |

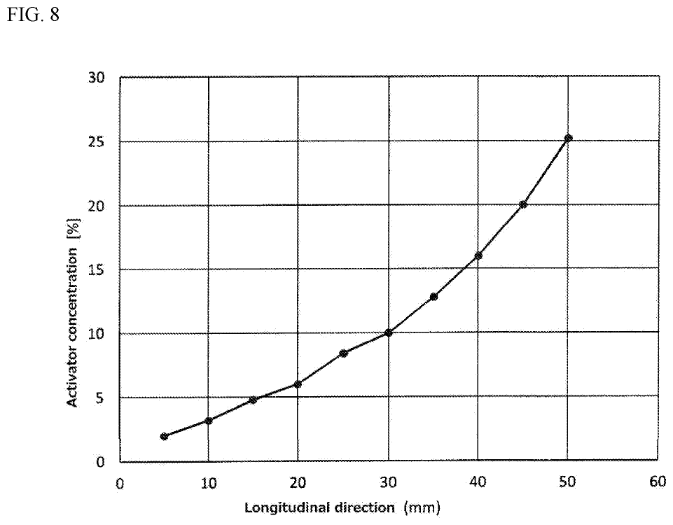

According to Table 1 and FIG. 8, it can be confirmed that the concentration gradient of the activator existed along the longitudinal direction of the phosphor.

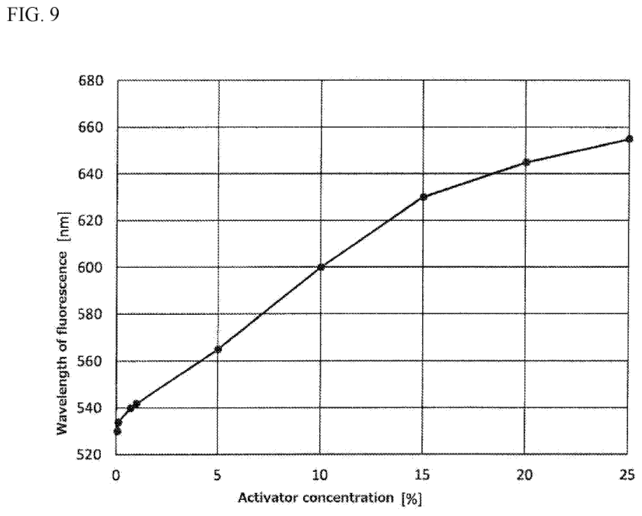

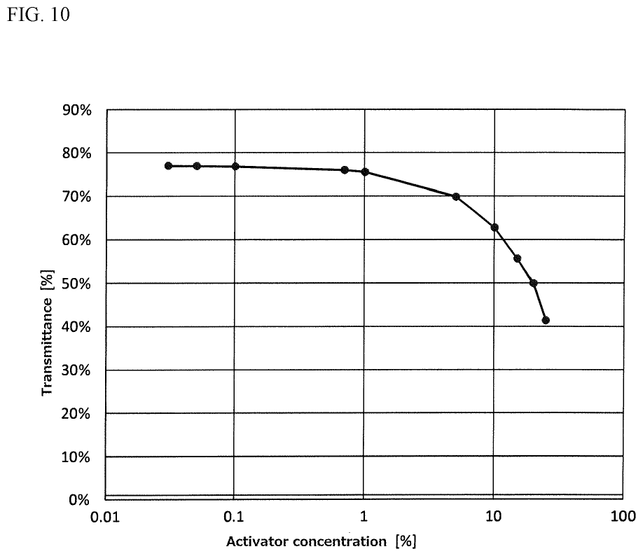

According to Table 1, FIG. 9, and FIG. 10, it was confirmed that when the activator concentration was low, the wavelength of the fluorescence tended to be shorter, and the transmittance tended to be higher.

According to Table 1, FIG. 9, and FIG. 10, when the activator concentration was high, the wavelength of the fluorescence tended to be longer, and the transmittance tended to be lower.

### NUMERICAL REFERENCES

2,2a,2b,2c,2d . . . Light emitting device
4 . . . Phosphor
4a . . . First surface
4b . . . Second surface
6 . . . Reflection board
8 . . . Cover
10,10a,10b,10c,10d,10e . . . Blue light emitting element
12 . . . Rotating unit
14 . . . Reflection unit
16 . . . Polarizing unit
22 . . . Single crystal manufacturing apparatus
24 . . . Crucible
26 . . . Refractory furnace
28 . . . Quartz tube
30 . . . Induction heating coil
32 . . . Seed crystal holding jig
34 . . . Seed crystal
36 . . . After heater

1. A phosphor comprising an activator, wherein the phosphor has a concentration gradient of the activator formed at least along one direction.

2. The phosphor according to claim 1, wherein the phosphor is a columnar shape, and the phosphor has the concentration gradient of the activator along a longitudinal direction of the phosphor.

3. The phosphor according to claim 1, wherein the concentration gradient of the activator is formed along a direction perpendicular to a direction of an optical path of a light transmitting through the phosphor.

4. The phosphor according to claim 1, wherein the phosphor is a single crystal.

5. The phosphor according to claim 1, wherein the activator is a heavy metal element or a rare earth element.

6. The phosphor according to claim 1, wherein an activator concentration represents a ratio of an amount of the activator with respect to an amount of elements other than oxygen included in the phosphor, and the activator concentration in the phosphor is 0.05 mol % or more and 20 mol % or less.

7. The phosphor according to claim 1, wherein a wavelength of a fluorescence of the phosphor is 530 nm to 645 nm.

8. The phosphor according to claim 1, wherein the activator is at least one selected from the group consisting of Ce, Pr, Sm, Eu, Tb, Dy, Tm, and Yb.

9. A light emitting device comprising the phosphor according to claim 1, and a means for changing an incident position of a light for exciting the phosphor emitted from a light source.

10. The light emitting device according to claim 9 comprising the light source, and the light source is at least one of a blue light emitting diode and a blue semiconductor laser.
